(19) United States
(12) Patent Application Publication
(10) Pub. No.: US 2026/0107396 A1
(43) Pub. Date: Apr. 16, 2026

(54) LOCKING DEVICE, DISPLAY DEVICE AND SPLICING METHOD

(71) Applicant: Shanghai Tianma Micro-electronics Co., Ltd., Shanghai (CN)

(72) Inventors: Kaikai ZHANG, Shanghai (CN); Yongxin HE, Shanghai (CN); Yuan DING, Shanghai (CN); Jujian FU, Shanghai (CN)

(21) Appl. No.: 18/965,545

(22) Filed: Dec. 2, 2024

(30) Foreign Application Priority Data
Oct. 15, 2024 (CN) 202411442372.X

(51) Int. Cl. H05K 5/02; H05K 5/00

(52) U.S. Cl. CPC H05K 5/0221; H05K 5/30

(57) ABSTRACT

A locking device includes a bracket and a support plate arranged opposite to each other, a side of the support plate facing away from the bracket being used for carrying a display unit. One of the bracket and the support plate includes a first pin, and the other one of the bracket and the support plate includes a first switch. When the first switch is in a locked state, the first pin is inserted into the first switch, and the first switch resists the first pin from being pulled out. One of the bracket and the support plate includes a second pin, and the other one of the bracket and the support plate includes a second switch. When the second switch is in the locked state, the second pin is inserted into the second switch, and the second switch resists further insertion of the second pin.

### CROSS-REFERENCE TO RELATED APPLICATION

This application claims the priority of Chinese Patent Application No. 202411442372.X, filed on Oct. 15, 2024, the content of which is incorporated herein by reference in its entirety.

### TECHNICAL FIELD

The application relates to the field of display technology, and in particular to a locking device, a display device and a splicing method.

### BACKGROUND

A display device with a flexibly detachable display unit may meet various display requirements, such as displaying a larger area or more shapes. However, during the installation and use of the display unit, how to ensure the flatness of the display surface of the display unit is the key to improving the display performance of the display device.

### SUMMARY

In order to solve the aforementioned technical problems, the embodiments of the present disclosure provide a locking device, a display device and a splicing method.

In one aspect, the present disclosure provides a locking device, and the locking device includes a bracket and a support plate arranged opposite to each other, a side of the support plate facing away from the bracket being used for carrying a display unit, where one of the bracket and the support plate includes a first pin, and the other one of the bracket and the support plate includes a first switch, when the first switch is in a locked state, the first pin is inserted into the first switch, and the first switch resists the first pin from being pulled out; and one of the bracket and the support plate includes a second pin, and the other one of the bracket and the support plate includes a second switch, when the second switch is in the locked state, the second pin is inserted into the second switch, and the second switch resists further insertion of the second pin.

In another aspect, the present disclosure provides a display device including a locking device, and the locking device includes a bracket and a support plate arranged opposite to each other, a side of the support plate facing away from the bracket being used for carrying a display unit, where one of the bracket and the support plate includes a first pin, and the other one of the bracket and the support plate includes a first switch, when the first switch is in a locked state, the first pin is inserted into the first switch, and the first switch resists the first pin from being pulled out; and one of the bracket and the support plate includes a second pin, and the other one of the bracket and the support plate includes a second switch, when the second switch is in the locked state, the second pin is inserted into the second switch, and the second switch resists further insertion of the second pin. The display device includes a display panel, and the display panel is located on a side of the support plate away from the bracket.

In another aspect, the present disclosure provides a splicing method, and the splicing method includes respectively attaching a plurality of display units to their corresponding support plates, where display surfaces of the display units are located on a side of the display units away from the support plates; detachably connecting each support plate to a bracket from a side of the support plate away from a display unit, where one of the bracket and the support plate includes a first pin, and the one of the bracket and the support plate includes a first switch, and by inserting the first pin into the first switch and controlling the first switch to be in a locked state, so that the first switch locks the first pin and resists the first pin from being pulled out, one of the bracket and the support plate includes a second pin, and the other one of the bracket and the support plate includes a second switch, and by inserting the second pin into the second switch and controlling the second switch to be in the locked state, so that the second switch locks the second pin and resists further insertion of the second pin; placing each of the display units on a same platform from a display surface side of each display unit; and by adjusting a locking height of the first switch to the first pin between each support plate and the bracket and a locking height of the second switch to the second pin, making the display surface of each display unit fit with the platform, thereby completing a splicing of each of the display units.

Other aspects of the present disclosure can be understood by those skilled in the art in light of the description, the claims, and the drawings of the present disclosure.

### BRIEF DESCRIPTION OF THE DRAWINGS

In order to more thoroughly illustrate the technical solutions of the embodiments of the present disclosure, the drawings essential for understanding the embodiments will be briefly introduced hereinafter. Apparently, the drawings described below are merely some embodiments of the present disclosure. For a person skilled in the art, other drawings may be obtained based on these drawings without making creative efforts.

FIG. 1 is a schematic cross-sectional view of a locking device, in accordance with an embodiment of the present disclosure;

FIG. 2 is a schematic cross-sectional view of a locking device when a first switch is in a locked state and a second switch is in a locked state, in accordance with an embodiment of the present disclosure;

FIG. 3 is a schematic structural diagram of a locking device, in accordance with an embodiment of the present disclosure;

FIG. 4 is a partial exploded view of a locking device, in accordance with an embodiment of the present disclosure;

FIG. 5 is a cross-sectional structural diagram of a first pin and a first switch in a locking device, in accordance with an embodiment of the present disclosure;

FIG. 6 is a schematic diagram of FIG. 5;

FIG. 7 is a schematic diagram showing a force applied to a ball/cylinder in an engaging member when a first switch in a locking device is in a locked state, in accordance with an embodiment of the present disclosure;

FIG. 8 is a schematic diagram showing force applied to a ball/cylinder in an engaging member when a first switch in a locking device is in a locked state and a first pin is forcibly pulled out, in accordance with an embodiment of the present disclosure;

FIGS. 9A-9D are schematic diagrams of several states of a first pin being inserted into a first switch and being locked by the first switch;

FIG. 10 is a schematic diagram of the cross-section AA′ in FIG. 1;

FIG. 11 is a schematic top view of a second switch in a locking device, in accordance with an embodiment of the present disclosure;

FIG. 12 is a schematic top view of another second switch in a locking device, in accordance with an embodiment of the present disclosure;

FIG. 13A is a schematic cross-sectional structural diagram and an AA′ cross-sectional diagram of a locking device when a second switch is in an unlocked state, in accordance with an embodiment of the present disclosure;

FIG. 13B is a schematic cross-sectional structural diagram and an AA′ cross-sectional diagram of a second switch in a locking device when the second switch is in an intermediate state, in accordance with an embodiment of the present disclosure;

FIG. 13C is a schematic cross-sectional structural diagram and an AA′ cross-sectional diagram of a locking device when a second switch is in a locked state, in accordance with an embodiment of the present disclosure;

FIGS. 14-21 are schematic diagrams of several combinations of a first damping group composed of first pin and first switch and a second damping group composed of second pin and second switch in a locking device, in accordance with an embodiment of the present disclosure;

FIG. 22 is a schematic cross-sectional view of another locking device, in accordance with an embodiment of the present disclosure; and

FIGS. 23A-23E are schematic structural diagrams corresponding to each step in a splicing method, in accordance with an embodiment of the present disclosure.

Reference numerals: 100—bracket; 200—support plate; 300—display unit; 400—locking device; 500—display device; 600—platform; 10—first pin; 20—first switch; 30—second pin; 40—second switch; 21—first frame; 22—engaging member; 23—first elastic member; 24—baffle; K1—first through-hole; P1—first accommodating space; S1—first inclined plane; S2—second inclined plane; 41—second frame; 42—clamping member; 420—clamping part; 43—elastic assembly; 431—first sub—elastic assembly; 432—second sub—elastic assembly; 433—third sub—elastic assembly; 411—top; 412—sidewall; K3—third through—hole; P2—second accommodating space; S3—third inclined plane; S4—fourth inclined plane; M1—clamping surface; and K2—second through-hole.

### DETAILED DESCRIPTION

In order to better understand the technical solution of the present disclosure, the embodiments of the present disclosure are described in detail hereinafter with reference to the accompanying drawings. It should be noted that the described embodiments are merely part of the embodiments of the present disclosure, rather than all the embodiments of the present disclosure. Based on the embodiments in the present disclosure, all other embodiments obtained by a person skilled in the art without making creative work are within the scope of protection of the present disclosure.

In the following description, many specific details are set forth to facilitate a full understanding of the present disclosure, the present disclosure may also be implemented in other ways different from those described herein, and those skilled in the art may make similar generalizations without prejudice to the connotation of the present disclosure. Therefore, the present disclosure is not limited to the specific embodiments disclosed below.

As described in the background section, during the installation and use of a display unit, how to ensure the flatness of the display surface of the display unit is the key to improving the display performance of a display device.

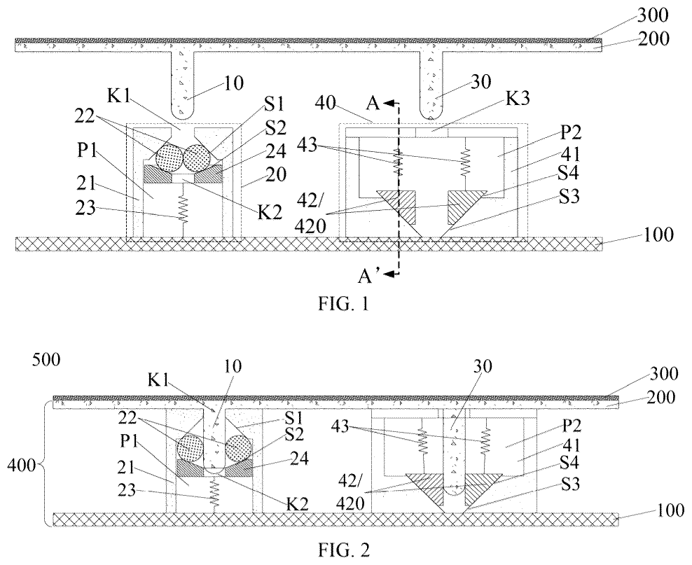

In view of the foregoing, an embodiment of the present disclosure provides a locking device. FIG. 1 is a schematic diagram of the cross-sectional structure of a locking device in accordance with an embodiment of the present disclosure. As shown in FIG. 1, the locking device includes a bracket 100 and a support plate 200 that are relatively arranged. The side of the support plate 200 facing away from the bracket 100 is used to support the display unit 300, and the display surface of the display unit 300 is located on the side of the display unit 300 facing away from the support plate 200.

As shown in FIG. 1, one of the bracket 100 and the support plate 200 includes a first pin 10, and the other includes a first switch 20. In other words, the bracket 100 includes the first pin 10 and the support plate 200 includes the first switch 20, or the bracket 100 includes the first switch 20 and the support plate 200 includes the first pin 10.

As shown in FIG. 1, one of the bracket 100 and the support plate 200 includes a second pin 30, and the other includes a second switch 40. In other words, the bracket 100 includes the second pin 30 and the support plate 200 includes the second switch 40, or the bracket 100 includes the second switch 40 and the support plate 200 includes the second pin 30.

It should be noted that the first pin 10 and the first switch 20 are arranged in a one-to-one correspondence, and the second pin 30 and the second switch 40 are arranged in a one-to-one correspondence. However, the present disclosure does not limit a situation where one of the bracket 100 and the support plate 200 includes the second pin 30 or the second switch 40 while also including the first pin 10. Similarly, the present disclosure does not limit a situation where one of the bracket 100 and the support plate 200 includes the second pin 30 or the second switch 40 while also including the first switch 20.

FIG. 2 is a schematic diagram of the cross-sectional structure of the locking device when the first switch 20 is in the locked state and the second switch 40 is in the locked state in accordance with an embodiment of the present disclosure. As shown in FIG. 2, when the first switch 20 is in the locked state, the first pin 10 is inserted into the first switch 20, and the first switch 20 resists the withdrawal of the first pin 10, so that the first pin 10 cannot be pulled out. When the second switch 40 is in the locked state, the second pin 30 is inserted into the second switch 40, and the second switch 40 resists further insertion of the second pin 30, so that the second pin 30 cannot be further inserted.

With such an arrangement, during the mounting and use of the display unit 300, after the flatness of the display surface of the display unit 300 is adjusted, the first switch 20 may be controlled to be in the locked state, and the first switch 20 may be configured to resist the withdrawal of the inserted first pin 10, thereby avoiding the increase of the distance between the bracket 100 and the support plate 200. The second switch 40 may be controlled to be in the locked state, and the second switch 40 may be configured to resist the further insertion of the inserted second pin 30, thereby avoiding the decrease of the distance between the bracket 100 and the support plate 200. That is, the distance between the bracket 100 and the support plate 200 is kept unchanged. Then the flatness of the display surface of the display unit 300 located on the side of the support plate 200 away from the bracket 100 is kept unchanged, thereby improving the display performance.

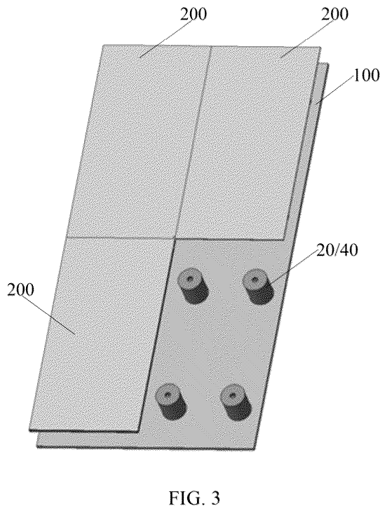

In some embodiments, as shown in FIG. 3, there are at least two support plates 200, so that each support plate 200 carries a display unit 300 on the side facing away from the bracket 100, and the display surface of the display unit 300 is located on the side of the display unit 300 facing away from the support plate 200. The locking device disclosed herein may then realize the splicing of at least two display units. During the splicing process of the at least two display units, the height/distance at which the first pin 10 is locked by the first switch 20 and the height/distance at which the second pin 30 is locked by the second switch 40 may be adjusted, thereby adjusting the flatness when splicing the at least two display units. After adjusting the flatness of the spliced at least two display units, due to the resistance of the first switch 20 to the withdrawal of the first pin 10 and the resistance of the second switch 40 to the further insertion of the second pin 30, the flatness of the spliced at least two display units may also be maintained unchanged, thereby improving the splicing display performance.

Certainly, the support plate 200 may also be one, as shown in FIGS. 1-2. In this way, after adjusting the flatness of the display surface of the display unit 300, the flatness of the display surface of the display unit 300 located on the side of the support plate 200 away from the bracket 100 may be kept unchanged, thereby improving the display performance.

In some embodiments, as shown in FIG. 1, the first switch 20 includes: a first frame 21, where the first frame 21 is provided with a first through-hole K1, the first through-hole K1 allows the first pin 10 to enter and exit, the first frame 21 has a first accommodating space P1, the first through-hole K1 is affixed with the first accommodating space P1, and the distance between at least a portion of the inner sidewall of the first frame 21 gradually narrows in a direction toward the first through-hole K1; an engaging member 22, where the engaging member is accommodated in the first accommodating space P1; and a first elastic member 23, where the first elastic member 23 is accommodated in the first accommodating space P1 and is located at a side of the engaging member 22 away from the first through-hole K1 to resist or push the engaging member 22.

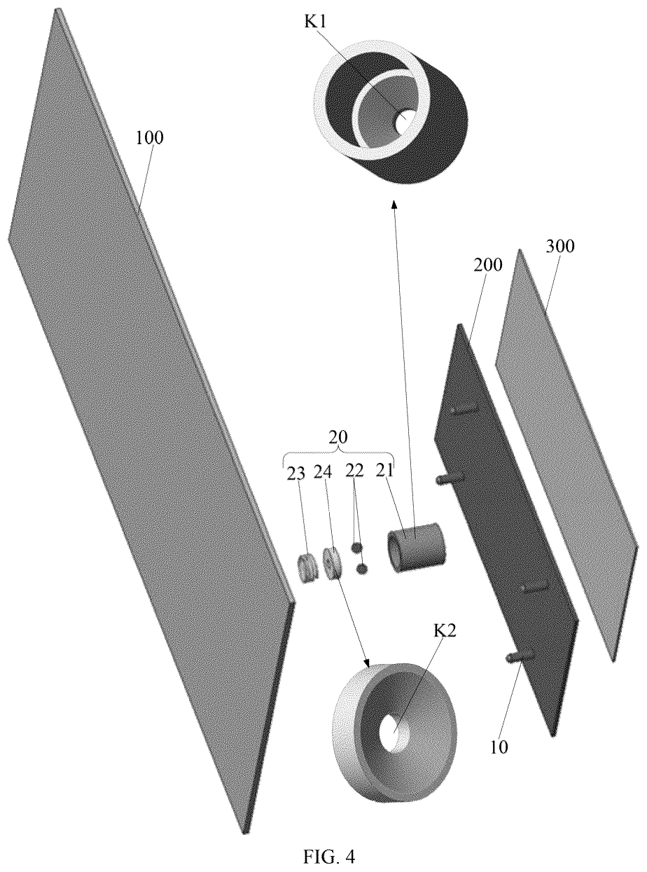

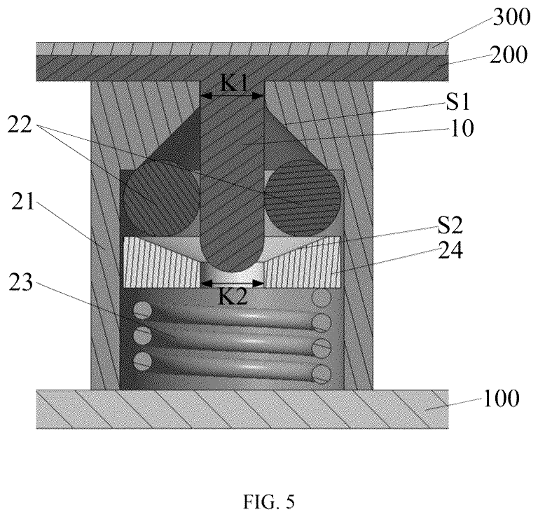

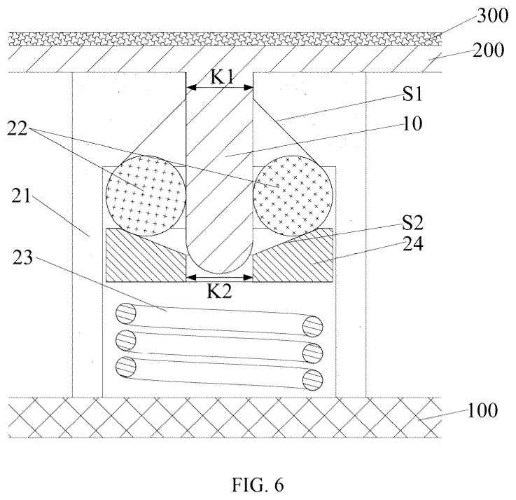

For ease of understanding, FIG. 4 is an exploded view of the first pin 10 and the first switch 20 in a locking device in accordance with an embodiment of the present disclosure. FIG. 4 also illustrates a structural diagram of the first frame 21 in the first switch 20. FIG. 5 is a cross-sectional structural diagram of the first pin 10 and the first switch 20 in a locking device in accordance with an embodiment of the present disclosure. FIG. 6 is a schematic diagram of FIG. 5.

Refer to FIGS. 4-6, the first frame 21 is provided with a first through-hole K1, and the first frame 21 has a first accommodating space P1. The first through-hole K1 is affixed to the first accommodating space P1, so that the first pin 10 may freely pass through the first through-hole K1 to enter the first accommodating space P1.

Refer to FIGS. 4-6, the first accommodating space P1 contains the engaging member 22 and the first elastic member 23, where the first elastic member 23 is located on the side of the engaging member 22 away from the first through-hole K1, and supports the engaging member 22. That is, the first elastic member 23 is compressed, exerting an elastic force to support the engaging member 22.

Refer to FIGS. 4-6, the distance between at least a portion of the inner sidewall of the first frame 21 gradually narrows in the direction toward the first through-hole K1. That is, at least a portion of the inner sidewall of the first frame 21 converges toward the first through-hole K1, so that at least part of the first accommodating space P1 narrows toward the first through-hole K1, or in other words, at least a portion of the inner sidewall of the first frame 21 is tapered and narrowed toward the first through-hole K1. In this way, when the first switch 20 is in the locked state, the first pin 10 passes through the first through-hole K1 and the engaging member 22 to enter the first accommodating space P1, and the engaging member 22 is accommodated in the space defined by the first pin 10, the first frame 21 (specifically the inner sidewall of the first frame 21) and the first elastic member 23 to resist the first pin 10 from being pulled out.

It should be noted that, as shown in FIG. 6, the more the first pin 10 is pulled out with force, the more the engaging member 22 is driven to move toward the angle between the first pin 10 and the inner sidewall of the first frame 21, where at least a portion of the inner sidewall of the first frame 21 tapers toward the first through-hole K1, so that at least part of the first accommodating space P1 is narrowed toward the first through-hole K1. Accordingly, the more the engaging member 22 tends to move toward the angle between the first pin 10 and the inner sidewall of the first frame 21, the greater the extrusion force of the engaging member 22 on the first pin 10, and the greater the extrusion force of the engaging member 22 on the inner sidewall of the first frame 21, and thus the greater the friction resistance between the engaging member 22 and the first pin 10 and between the engaging member 22 and the inner sidewall of the first frame 21, which prevents the first pin 10 from being pulled out. However, the first pin 10 may be further inserted into the first switch 20.

In some embodiments, as shown in FIG. 6, a portion of the inner sidewall of the first frame 21 may converge toward the first through-hole K1, so that part of the first accommodating space P1 is narrowed toward the first through-hole K1. Alternatively, the entire inner sidewall of the first frame 21 may converge toward the first through-hole K1, so that the entire first accommodating space P1 is narrowed toward the first through-hole K1, which is not limited in the present disclosure.

In some embodiments, as shown in FIG. 6, at least a portion of the inner sidewall of the first frame 21 is narrowed toward the first through-hole K1 in an inclined manner, so that the inner sidewall of the first frame 21 includes a first inclined plane S1 that gradually narrows in the direction toward the first through-hole K1. Therefore, when the first switch 20 is in the locked state, the angle between the first pin 10 passing through the engaging member 22 and the first inclined plane S1 is an acute angle, and the engaging member 22 is accommodated in the space defined by the first pin 10, the first inclined plane S1 and the first elastic member 23. When the first pin 10 is forcibly pulled out, the engaging member 22 tends to move toward the angle formed between the first pin 10 and the first inclined plane S1, which is more conducive to resisting the first pin 10 from being pulled out. Alternatively, at least a portion of the inner sidewall of the first frame 21 may also be converged toward the first through-hole K1 in the form of a concave surface, a stepped surface, etc., which is not limited in the present disclosure.

In some embodiments, the first elastic member 23 may be a spring.

In some embodiments, the engaging member 22 is ferromagnetic, so that a magnetic field may be applied to the first switch 20 to put the first switch 20 in an unlocked state. When the first switch 20 is in the unlocked state, the engaging member 22 is subjected to a magnetic field force in the magnetic field due to its ferromagnetism, so that the engaging member 22 pushes the first elastic member 23, so that the engaging member 22 no longer tightly squeezes the first pin 10, and even separates from the first pin 10, allowing the first pin 10 to move in and out freely.

In some embodiments, the engaging member 22 includes two balls. When the first switch 20 is in the pre-locked state, as shown in FIG. 1, the first pin 10 does not pass through the engaging member 22, and the two balls of the engaging member 22 fit each other. When the first switch 20 is in the locked state, as shown in FIGS. 2 and 5-6, the first pin 10 passes through the first through-hole K1 and the engaging member 22 to enter the first accommodating space P1, and the two balls of the engaging member 22 are located on two opposite sides of the first pin 10 and abut against the first pin 10.

It should be noted, alternatively, the engaging member 22 may also include two cylinders. When the first switch 20 is in the pre-locked state, as shown in FIG. 1, the first pin 10 does not pass through the engaging member 22, and the two cylinders of the engaging member 22 fit each other. When the first switch 20 is in the locked state, as shown in FIGS. 2 and 5-6, the first pin 10 passes through the first through-hole K1 and the engaging member 22 to enter the first accommodating space P1, and the two cylinders of the engaging member 22 are located on two opposite sides of the first pin 10 and abut against the first pin 10.

In summary, the first switch 20 is normally in a locked state, including a pre-locked state and a locked state. When the first switch 20 is in the pre-locked state, the two balls or cylinders of the engaging member 22 fit each other, and the first pin 10 does not pass through the engaging member 22. However, at this time, the engaging member 22 allows the first pin 10 to pass through, that is, the first pin 10 may pass through the engaging member 22. When the first switch 20 is in the locked state, the first pin 10 passes through the first through-hole K1 and the engaging member 22 to enter the first accommodating space P1. The two balls or cylinders of the engaging member 22 are located on two opposite sides of the first pin 10 and abut against the first pin 10 to resist the withdrawal of the first pin 10. However, at this time, the first pin 10 may be further inserted. A magnetic field may be applied to the first switch 20 to turn the first switch 20 from the locked state to the unlocked state, and the engaging member 22 pushes the first elastic member 23. The engaging member 22 is no longer restricted in the space defined by the first pin 10, the first inclined plane S1 and the first elastic member 23, allowing the first pin 10 to move in and out freely.

In some embodiments, as shown in FIGS. 1-2 and 4-6, the first switch 20 may further include a baffle 24, where the baffle 24 is accommodated in the first accommodating space P1 and located between the engaging member 22 and the first elastic member 23. The first elastic member 23 abuts against the engaging member 22 through the baffle 24. The baffle 24 is provided with a second through-hole K2, which corresponds to the first through-hole K1, allowing the first pin 10 to enter and exit. It should be noted that the first pin 10 must pass through the first through-hole K1 and the engaging member 22, and may pass through the second through-hole K2, or may not pass through the second through-hole K2, or may be inserted into the second through-hole K2, depending on the specific situations.

Furthermore, as shown in FIG. 6, the inner sidewall of the first frame 21 includes a first inclined plane S1, and the first inclined plane S1 gradually narrows in the direction toward the first through-hole K1. The surface of the baffle 24 that abuts against the engaging member 22 includes a second inclined plane S2, and the second inclined plane S2 and the first inclined plane S1 are arranged opposite to each other. In this way, when the first switch 20 is in the locked state, the first pin 10 passing through the engaging member 22 has an acute angle with the first inclined plane S1, and also has an acute angle with the second inclined plane S2, and the engaging member 22 is accommodated in the space defined by the first pin 10, the first inclined plane S1 and the second inclined plane S2, so as to resist the first pin 10 from being pulled out.

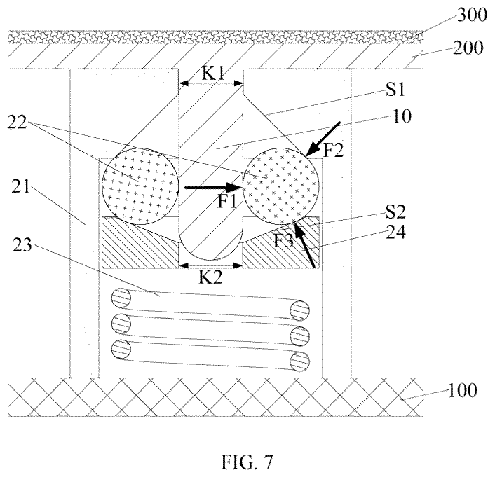

FIG. 7 illustrates the force conditions of the ball/cylinder in the engaging member 22 when the first switch 20 is in the locked state. As shown in FIG. 7, the first pin 10 has a resisting pressure F1 on the ball/cylinder in the engaging member 22, the first inclined plane S1 of the inner wall of the first frame 21 has a resisting pressure F2 on the ball/cylinder in the engaging member 22, and the second inclined plane S2 of the baffle 24 has a resisting supporting force F3 on the ball/cylinder in the engaging member 22 under the action of the first elastic member 23. These three forces and gravity keep the ball/cylinder in the engaging member 22 in a balanced force.

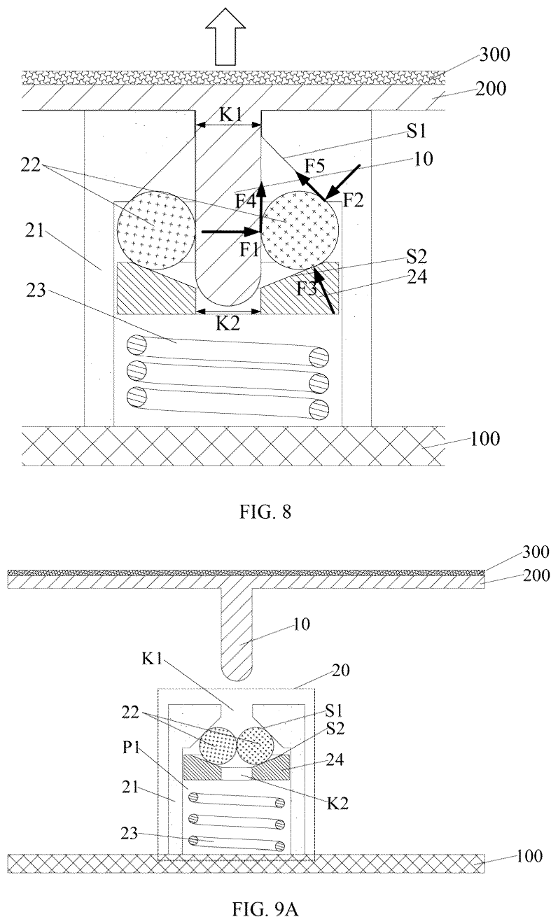

FIG. 8 illustrates the force applied to the ball/cylinder in the engaging member 22 when the first switch 20 is in the locked state and when the first pin 10 is pulled out with force. As shown in FIG. 8, when the first switch 20 is in the locked state and the first pin 10 is pulled out with force, the first pin 10 has a tendency to move outward relative to the ball/cylinder in the engaging member 22. The ball/cylinder in the engaging member 22 generates a friction force on the first pin 10. At the same time, the ball/cylinder in the engaging member 22 is also subjected to the friction force F4 generated by the first pin 10, driving the ball/cylinder in the engaging member 22, so that the ball/cylinder in the engaging member 22 has a tendency to move outward along the first inclined plane S1 toward the first through-hole. The ball/cylinder in the engaging member 22 tends to roll in the direction of the first through-hole K1, so that the ball/cylinder in the engaging member 22 is also subjected to the friction force F5 generated by the first inclined plane S1. The more the first pin 10 is pulled out with force, the more tightly the ball/cylinder in the engaging member 22 is confined in the space defined by the first pin 10, the first inclined plane S1 and the second inclined plane S2, so that the resisting pressure F1 between the ball/cylinder in the engaging member 22 and the first pin 10 and the resisting pressure F2 between the ball/cylinder in the engaging member 22 and the first inclined plane S1 both become larger, thereby increasing the friction resistance of the ball/cylinder in the engaging member 22 to the first pin 10, thereby resisting the first pin 10 from being pulled out.

It should be noted that due to the supporting effect of the second inclined plane S2 of the baffle 24 on the engaging member 22, when the first pin 10 is forcibly pulled out, the extrusion force between the first pin 10 and the engaging member 22 and the extrusion force between the engaging member 22 and the first inclined plane S1 are further increased, thereby further increasing the obstructive friction between the first pin 10 and the engaging member 22 and between the engaging member 22 and the first inclined plane S1, which may further resist the first pin 10 from being pulled out.

In some embodiments, when the first switch 20 is in the locked state, the bisector of the angle between the first pin 10 and the first inclined plane S1 passing through the engaging member 22 is perpendicular to the second inclined plane S2, so that when the first pin 10 is pulled out with force, the first pin 10 may be further resisted from being pulled out.

In some embodiments, at least one of the engaging members 22 and the baffle 24 is ferromagnetic, that is, the engaging member 22 is ferromagnetic, or the baffle 24 is ferromagnetic, or both the engaging member 22 and the baffle 24 are ferromagnetic. In this way, a magnetic field may be applied to the first switch 20 to put the first switch 20 in an unlocked state. When the first switch 20 is in the unlocked state, the engaging member 22 or the baffle 24 is subjected to a magnetic field force in the magnetic field due to its ferromagnetism, so that the engaging member 22 and the baffle 24 jointly push or press the first elastic member 23, so that the engaging member 22 no longer tightly squeezes the first pin 10, or even separates from the first pin 10, allowing the first pin 10 to move in and out freely.

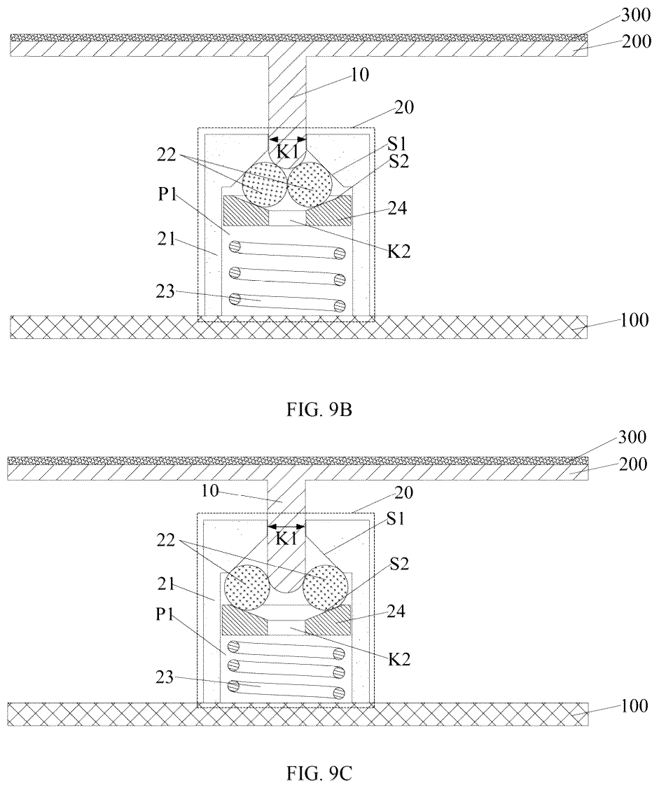

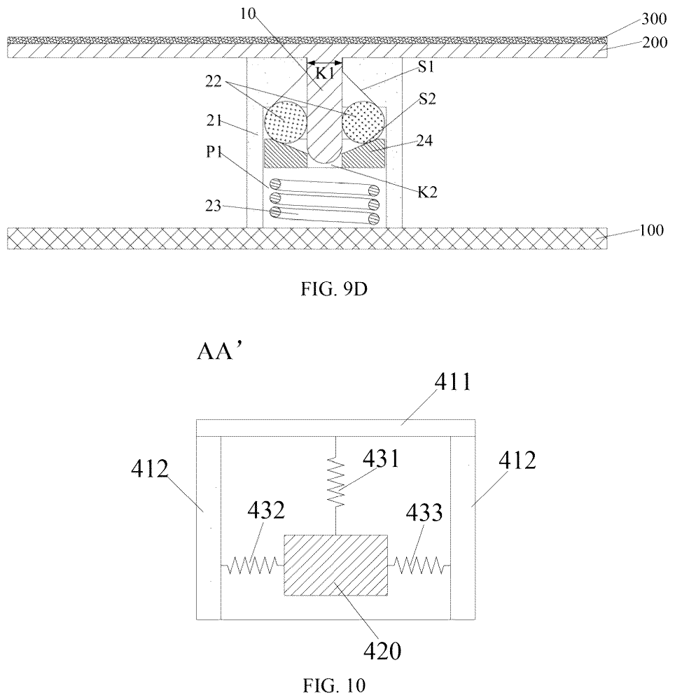

FIGS. 9A-9D illustrate schematic diagrams of several states of the first pin 10 being inserted into the first switch 20 and being locked by the first switch 20. As shown in FIG. 9A, the first pin 10 has not yet been inserted into the first switch 20, the first switch 20 is in a pre-locked state, and the two balls/cylinders of the engaging member 22 in the first switch 20 are in contact with each other. Refer to FIG. 9B, the first pin 10 is inserted into the first through-hole K1, but has not yet passed through the engaging member 22, and the first switch 20 is still in a pre-locked state. Refer to FIG. 9C, the first pin 10 is passing through the engaging member 22, and the engaging member 22 is about to generate a force to resist the first pin 10 from being pulled out. Refer to FIG. 9D, the first pin 10 has passed through the engaging member 22, and the engaging member 22 is already able to resist the first pin 10 from being pulled out.

In some embodiments, as shown in FIG. 1, the second switch 40 includes: a second frame 41, where the second frame 41 is provided with a third through-hole K3, the third through-hole K3 allows the second pin 30 to enter and exit, the second frame 41 has a second accommodating space P2, the third through-hole K3 is affixed to the second accommodating space P2, the inner sidewall of the second frame 41 includes a third inclined plane S3, and the third inclined plane S3 is gradually narrowed in a direction away from the third through-hole K3; a clamping member 42, where the clamping member 42 is accommodated in the second accommodating space P2, and the clamping member 42 includes at least two clamping parts 420, each of which is disposed around the third through-hole K3; and at least two sets of elastic assemblies 43 accommodated in the second accommodating space P2, where the elastic assemblies 43 and the clamping parts 420 are connected one by one. The clamping parts 420 are connected to the second frame 41 through the elastic assemblies 43 and are held on the third inclined plane S3 by the elastic assemblies 43.

It should be noted that the inner wall of the second frame 41 includes a third inclined plane S3 that gradually narrows in a direction away from the third through-hole K3. The inner wall of the second frame 41 as a whole gradually narrows in a direction away from the third through-hole K3 to form the third inclined plane S3, or part of the inner wall of the second frame 41 gradually narrows in a direction away from the third through-hole K3 to form the third inclined plane S3, depending on the specific circumstances.

It should also be noted that a clamping part 420 is connected to the second frame 41 through an elastic assembly 43 and is held on the third inclined plane S3 by the elastic assembly 43. In this way, the clamping part 420 is subjected to the elastic force of the elastic assembly 43, the supporting force of the third inclined plane S3 and gravity, thereby maintaining force balance.

In this way, when the second switch 40 is in the locked state, as shown in FIG. 2, the second pin 30 enters the second accommodating space P2 through the third through-hole K3 and is clamped by each clamping part 420. The clamping part 420 is accommodated in the space defined by the second pin 30, the third inclined plane S3 and the correspondingly connected elastic assembly 43, resisting further insertion of the second pin 30.

When the second switch 40 is in the locked state, an elastic assembly 43 may be configured to have an elastic force on the connected clamping part 420 in the direction away from the third through-hole K3, so that if the second pin 30 is to be further inserted, the greater the extrusion force between the second pin 30 and each clamping part 420, the greater the friction resistance to the second pin 30, which hinders the further insertion of the second pin 30. However, when the second switch 40 is in the locked state, the second pin 30 may be pulled out by force.

In some embodiments, as shown in FIG. 1, the clamping part 420 has a fourth inclined plane S4, which abuts against the third inclined plane S3. That is, the clamping part 420 abuts against the third inclined plane S3 through the fourth inclined plane S4, so that the clamping part 420 is similar to a wedge block, and the clamping part 420 is placed more stably on the third inclined plane S3.

To facilitate understanding of the connection relationship between the clamping part 420 and the elastic assembly 43, FIG. 10 is a schematic diagram of the AA′ section in FIG. 1. Refer to FIGS. 1 and 10, the second frame 41 includes a top 411 and a sidewall 412, and the top 411 is provided with a third through-hole K3. The elastic assembly 43 includes a first sub-elastic member 431, a second sub-elastic member 432 and a third sub-elastic member 433. The first sub-elastic member 431 is connected between the top 411 of the second frame 41 and the clamping part 420. The second sub-elastic member 432 is connected between the sidewall 412 of the second frame 41 and the clamping part 420, and the third sub-elastic member 433 is connected between the sidewall 412 of the second frame 41 and the clamping part 420, and the second sub-elastic member 432 and the third sub-elastic member 433 are located on two opposite sides of the clamping part 420.

In some embodiments, the first sub-elastic member 431, the second sub-elastic member 432, and the third sub-elastic member 433 may be springs.

In practical applications, the first sub-elastic member 431, the second sub-elastic member 432 and the third sub-elastic member 433 may be set in a compressed state to have an elastic force to push the connected clamping part 420. It is understood that since the first sub-elastic member 431, the second sub-elastic member 432 and the third sub-elastic member 433 are located in a same plane, the connected clamping part 420 will pop out in a direction perpendicular to the plane where the first sub-elastic member 431, the second sub-elastic member 432 and the third sub-elastic member 433 are located. To this end, a third inclined plane S3 is set on the inner sidewall of the second frame 41 in a direction away from the third through-hole K3, and the clamping part 420 is configured to have a fourth inclined plane S4, and the fourth inclined plane S4 abuts against the third inclined plane S3, so that the clamping part 420 is pushed against the third inclined plane S3 and the force is balanced.

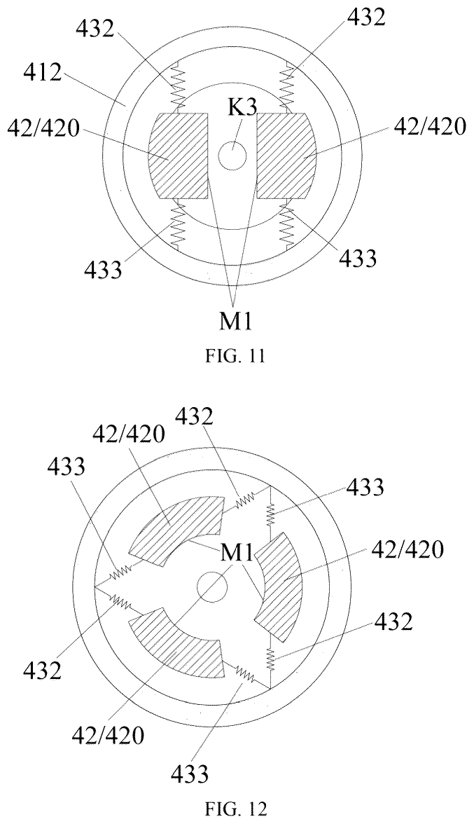

FIG. 11 illustrates a schematic top view of a second switch 40 in the locking device in accordance with an embodiment of the present disclosure. As shown in FIG. 11, the clamping member 42 includes two clamping parts 420, which are located on two opposite sides of the third through-hole K3 and surround the third through-hole K3.

FIG. 12 illustrates a top view of another second switch 40 in the locking device in accordance with an embodiment of the present disclosure. As shown in FIG. 12, the clamping member 42 includes three clamping parts 420, and the three clamping parts 420 surround the third through-hole K3.

It should be noted that the clamping member 42 may include four or more clamping parts 420, and each clamping part 420 may be disposed around the third through-hole K3.

As shown in FIGS. 11-12, the clamping part 420 has a clamping surface M1. When the second switch 40 is in the locked state, the clamping surface M1 of the clamping part 420 abuts against the second pin 30, that is, the clamping surface M1 of the clamping part 420 contacts the second pin 30. As shown in FIG. 11, the clamping surface M1 of the clamping part 420 is a flat surface. Alternatively, as shown in FIG. 12, the clamping surface M1 of the clamping part 420 is a curved surface, so as to clamp the second pin 30 more tightly, enhance the clamping friction between the clamping part 420 and the second pin 30, and resist further insertion of the second pin 30.

In some embodiments, the clamping surface M1 of the clamping part 420 further includes threads, that is, the clamping surface M1 of the clamping part 420 is a threaded tooth surface, which may further enhance the clamping friction between the clamping part 420 and the second pin 30 and resist further insertion of the second pin 30.

In some embodiments, at least part of the clamping part 420 is magnetic, and the magnetic field of the clamping part 420 has a magnetic field component at least in the direction in which the bracket 100 and the support plate 200 are relatively arranged. In this way, when applying the magnetic field to the second switch 40, the clamping part 420 may be subjected to the magnetic field force along the direction in which the bracket 100 and the support plate 200 are relatively arranged, so that the elements of the clamping part 420 may move away from or close to each other along the third inclined plane S3, thereby controlling the second switch 40 to be in different states.

The various states of the second switch 40 are described below.

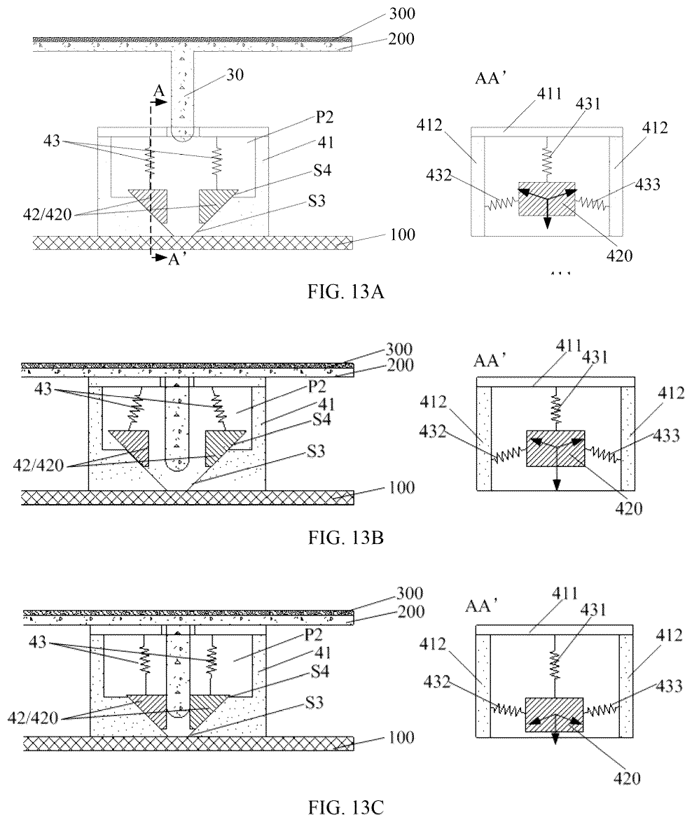

When the second switch 40 is in the unlocked state, as shown in FIGS. 1 and 13A, each clamping part 420 is held against the third inclined plane S3 by the connected first sub-elastic member 431, the second sub-elastic member 432 and the third sub-elastic member 433, allowing the second pin 30 to freely enter and exit. That is, the second pin 30 may enter the second accommodating space P2 through the third through-hole K3, and freely enter and exit between each clamping part 420. Here, the first sub-elastic member 431, the second sub-elastic member 432 and the third sub-elastic member 433 are all in a compressed state, and have an elastic force against the connected clamping part 420, as shown by the arrow in FIG. 13A.

By applying a magnetic field to the second switch 40, the second switch 40 may be converted from the unlocked state to the intermediate state. When the second switch 40 is in the intermediate state, as shown in FIG. 13B, since at least part of the clamping part 420 is magnetic, and the magnetic field of the clamping part 420 has a component at least in the direction in which the bracket 100 and the support plate 200 are relatively arranged. After applying the magnetic field to the second switch 40, each clamping part 420 may be subjected to the magnetic field force in the direction in which the bracket 100 and the support plate 200 are relatively arranged, so that each clamping part 420 presses against the first sub-elastic member 431 upward along the third inclined plane S3. The first sub-elastic member 431 is compressed more severely, and the first sub-elastic member 431 accumulates elastic potential energy. Since each clamping part 420 presses against the first sub-elastic member 431 upward along the third inclined plane S3, each clamping part 420 moves away from each other, allowing the second pin 30 to freely enter and exit.

It should be noted that, by comparing FIG. 13A with FIG. 13B, when the second switch 40 is in the intermediate state, compared to when the second switch 40 is in the unlocked state, the second sub-elastic member 432 and the third sub-elastic member 433 are relatively elongated, and the elastic force of the first sub-elastic member 431 on the clamping part 420 becomes greater.

After the second pin 30 is inserted to a moderate depth of the second switch 40, the magnetic field is quickly removed, and the elastic potential energy accumulated in the first sub-elastic member 431 is converted into kinetic energy of the clamping part 420, so that each clamping part 420 quickly moves toward each other along the third inclined plane S3 under the elastic force of the connected first sub-elastic member 431, clamping the second pin 30, so that the second switch 40 is in the locked state. As shown in FIG. 13C, when the second switch 40 is in the locked state, each clamping part 420 clamps the second pin 30, and each clamping part 420 is accommodated in the space defined by the second pin 30, the third inclined plane S3 and the correspondingly connected first sub-elastic member 431, the second sub-elastic member 432 and the third sub-elastic member 433, thereby resisting further insertion of the second pin 30.

When the second switch 40 is in the locked state, as shown in FIG. 13C, the first sub-elastic member 431, the second sub-elastic member 432 and the third sub-elastic member 433 are still in the compressed state, and have a resisting elastic force on the clamping part 420, so that the clamping part 420 is resisted between the second pin 30 and the third inclined plane S3. When the second pin 30 is to be further inserted, due to the resisting elastic force of the first sub-elastic member 431, the second sub-elastic member 432 and the third sub-elastic member 433 on the clamping part 420, the greater the extrusion force between the second pin 30 and each clamping part 420, the greater the friction resistance to the second pin 30, which hinders the second pin 30 from being further inserted.

It should be noted that after applying the magnetic field to the second switch 40 again, each clamping part 420 is subjected to a magnetic field force in the direction in which the bracket 100 and the support plate 200 are relatively arranged, so that each clamping part 420 presses upward against the first sub-elastic member 431 along the third inclined plane S3, thereby converting the second switch 40 from the locked state to the intermediate state. After the second pin 30 is pulled out, the magnetic field is slowly removed, although the elastic potential energy accumulated in the first sub-elastic member 431 will also be converted into the kinetic energy of the clamping part 420, but because the magnetic field is pulled out slowly, each clamping part 420 slowly returns to the balanced position where the second switch 40 is in the unlocked state.

From the above description, it can be seen that the first switch 20 controlling the first pin 10 is normally in the locked state, which may be turned to an unlocked state under the action of a magnetic field. When the first switch 20 is in the locked state, the first switch 20 has the effect of resisting the withdrawal of the inserted first pin, so as to resist the increase of the distance between the bracket 100 and the support plate 200 carrying the display unit 300. The second switch 40 controlling the second pin 30 is a bistable switch, which may be converted from the unlocked state to the locked state by applying a magnetic field once and withdrawing, and may be converted from the locked state to the unlocked state by applying a magnetic field again and withdrawing. When the second switch 40 is in the locked state, it has the effect of resisting the further insertion of the inserted second pin 30, so as to resist the decrease of the distance between the bracket 100 and the support plate 200 carrying the display unit 300.

Accordingly, the first pin 10 and the first switch 20 form a first damping group R1 to resist the increase of the distance between the bracket 100 and the support plate 200 carrying the display unit 300, and the second pin 30 and the fourth switch 40 form a second damping group R2 to resist the decrease of the distance between the bracket 100 and the support plate 200 carrying the display unit 300. After the flatness of the display surface of the display unit 300 is adjusted, the distance between the bracket 100 and the support plate 200 may be kept unchanged by the first damping group R1 and the second damping group R2, thereby maintaining the flatness of the display surface of the display unit 300 located on the side of the support plate 200 away from the bracket 100, thereby improving the display performance.

It should be noted that, between the bracket 100 and the support plate 200, there may be one or more first damping groups R1, and there may also be one or more second damping groups R2, which will be described in detail in the following embodiments.

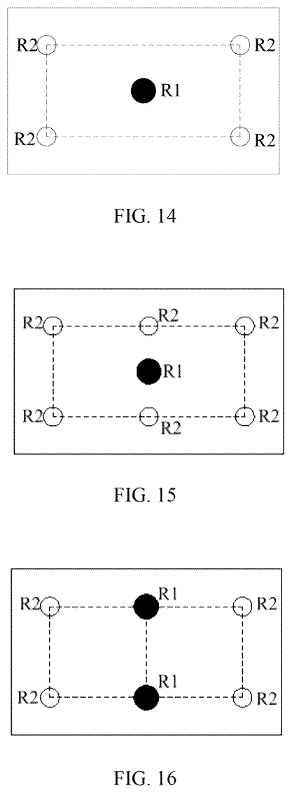

In some embodiments, as shown in FIGS. 14-15 , when a single first damping group R1 corresponds to a second damping group array composed of multiple second damping groups R2, the distance between the geometric center of the single first damping group R1 and the geometric center of the corresponding second damping group array is less than a first predefined range. That is, the geometric center of the single first damping group R1 is close to the geometric center of the corresponding second damping group array. In an optimal situation, the two centers are almost overlapping.

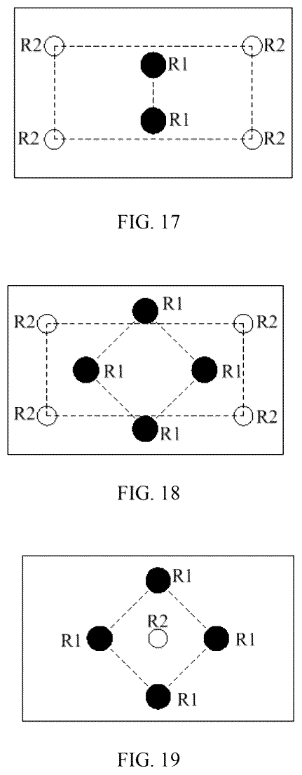

In another embodiment, as shown in FIGS. 16-17, when two first damping groups R1 correspond to a second damping group array composed of multiple second damping groups R2, the distance between the center of the line connecting the geometric centers of the two first damping groups R1 and the geometric center of the corresponding second damping group array is less than a second predefined range. That is, the center of the line connecting the geometric centers of the two first damping groups R1 is close to the geometric center of the corresponding second damping group array. In an optimal situation, the two centers are almost overlapping.

In some embodiments, as shown in FIG. 18, when a first damping group array composed of multiple first damping groups R1 corresponds to a second damping group array composed of multiple second damping groups R2, the distance between the geometric center of the first damping group array and the geometric center of the corresponding second damping group array is less than a third predefined range. That is, the geometric center of the first damping group array is close to the geometric center of the corresponding second damping group array. In an optimal situation, the two centers are almost overlapping.

In some embodiments, as shown in FIG. 19, when a first damping group array composed of multiple first damping groups R1 corresponds to a single second damping group, the distance between the geometric center of the first damping group array and the geometric center of the corresponding single second damping group R2 is less than a fourth predefined range. That is, the geometric center of the first damping group array is close to the geometric center of the corresponding single second damping group R2. In an optimal situation, the two centers are almost overlapping.

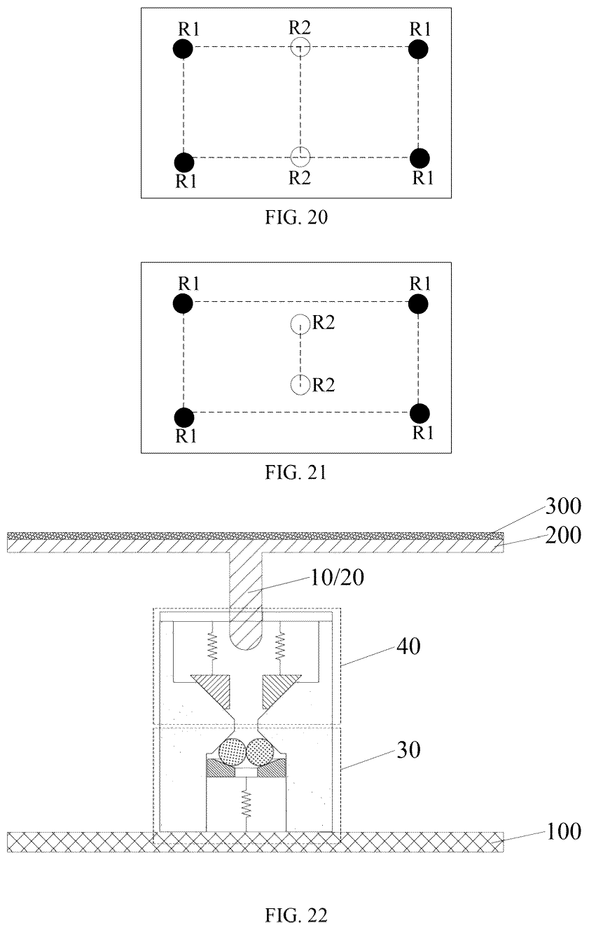

In some embodiments, as shown in FIGS. 20-21, when a first damping group array composed of multiple first damping groups R1 corresponds to two second damping groups R2, the distance between the geometric center of the first damping group array and the center of the line connecting the geometric centers of the corresponding two second damping groups R2 is less than a fifth predefined range. That is, the geometric center of the first damping group array is close to the geometric center of the corresponding two second damping groups R2. In an optimal situation, the two centers are almost overlapping.

The aforementioned first predefined range, second predefined range, third predefined range, fourth predefined range and fifth predefined range may be set according to actual needs and may be specific distance range values, or may be configured in view of the intervals between the first pins 10, the intervals between the second pins 30, and the intervals between a first pin 10 and a second pin 30. For example, when there are multiple first pins 10, a predefined range may be set to be less than half of the minimum interval between the first pins 10.

The aforementioned methods are intended to make the action point where the first damping group R1 resists the increase in the distance between the bracket 100 and the support plate 200 close to the action point where the second damping group R2 resists the decrease in the distance between the bracket 100 and the support plate 200, thereby maintaining the flatness of the display surface of the display unit 300 carried by the support plate 200 unchanged.

It should be noted that FIGS. 14-21 only lists a limited number of scenarios in which the geometric centers of the first damping group array formed by the first damping group R1 or the first damping group R1 almost coincide with the geometric centers of the second damping group array formed by the second damping group R1 or the second damping group R2. Other scenarios including that the geometric centers of the first damping group array formed by the first damping group R1 or the first damping group R1 almost coincide with the geometric centers of the second damping group array formed by the second damping group R1 or the second damping group R2 may also be derived, details of which are not repeated here.

It should also be noted that FIGS. 14-21 illustrating the locking device as a rectangle are merely for illustrative purposes, but not intended to limit the shape of the locking device.

In some embodiments, as shown in FIG. 22, the first pin 10 and the second pin 30 may be made into an integrally formed structure, and the first switch 20 and the second switch 40 may be stacked along the direction in which the bracket 100 and the support plate 200 are relatively arranged. In this way, the integrally formed pin may be inserted into the second switch 40 and the first switch 20 successively, so that the first switch 20 has a function of resisting the withdrawal of the integrally formed pin, and the second switch 40 has a function of resisting further insertion of the integrally formed pin. In this way, the geometric centers of the first damping group R1 formed by the first pin 10 and the first switch 20 coincide with the geometric centers of the second damping group R2 formed by the second pin 30 and the second switch 40, thereby simplifying the structure design.

Correspondingly, the embodiments of the present disclosure also provide a display device. As shown in FIG. 2, and the display device 500 includes the locking device 400. In other words, the display device 500 includes a bracket 100, a support plate 200, and a first pin 10, a first switch 20, a second pin 30, and a second switch 40 located between the bracket 100 and the support plate 200. The display device 500 also includes a display panel, that is, the aforementioned display unit 300, which is located on the side of the support plate 200 away from the bracket 100 and is used to display images. Since the locking device 400 may keep the distance between the bracket 100 and the support plate 200 unchanged, and thus keep the flatness of the display surface of the display panel located on the side of the support plate 200 away from the bracket 100 unchanged, thereby improving the display performance of the display device.

In some embodiments, there may be two or more support plates 200, and the display device 500 may be a display device formed by splicing two or more display panels.

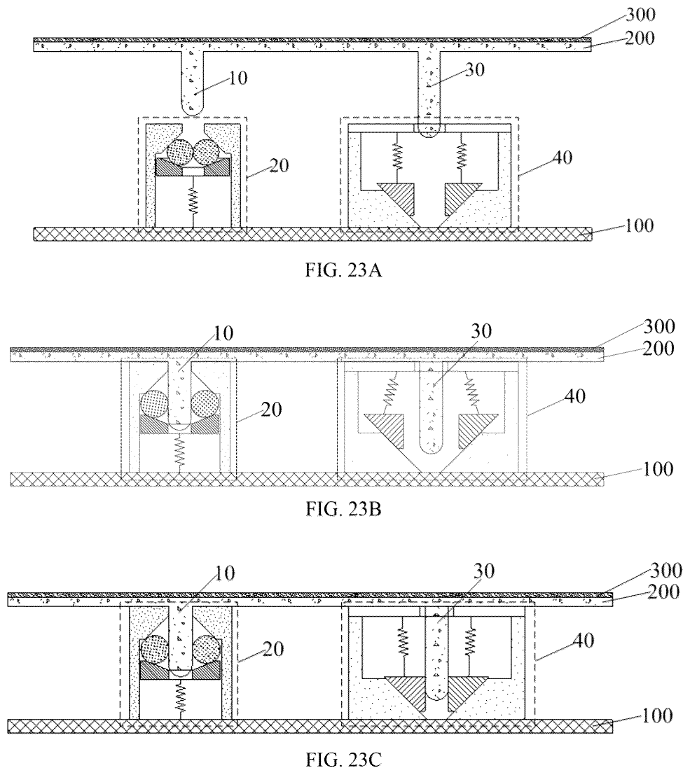

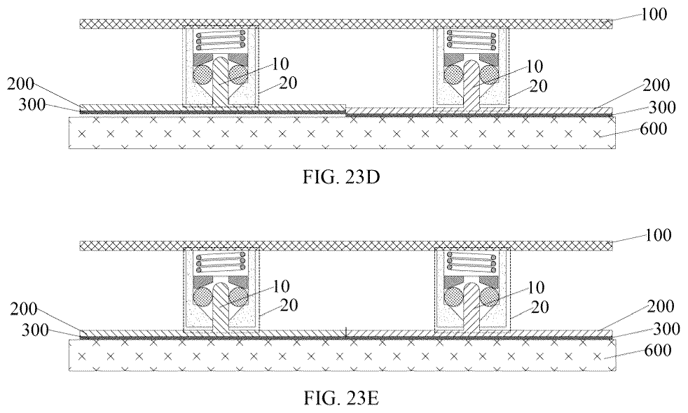

Furthermore, the embodiments of the present disclosure further provide a splicing method, which includes:
S100: As shown in FIG. 23A, a plurality of display units 300 are respectively attached to their corresponding support plates 200, with the display surface of the display units 300 being located on the side of the display units 300 away from the support plate 200.
S200: As shown in FIGS. 23A-23C, each support plate 200 is detachably connected to the bracket 100 from the side of the support plate 200 away from the display unit 300.

Here, one of the bracket 100 and the support plate 200 includes a first pin 10, and the other includes a first switch 20. By inserting the first pin 10 into the first switch 20 and controlling the first switch 20 to be in the locked state, the first switch 20 locks the first pin 10 and resists the first pin 10 from being pulled out. In addition, one of the bracket 100 and the support plate 200 includes a second pin 30, and the other includes a second switch 40. By inserting the second pin 30 into the second switch 40 and controlling the second switch 40 to be in the locked state, the second switch 40 locks the second pin 30 and resists further insertion of the second pin 30.

Corresponding to the above embodiments, the first switch 20 is normally in a locked state. Therefore, by directly inserting the first pin 10 into the first switch 20, the first switch 20 may be controlled to be in a locked state, so that the first switch 20 locks the first pin 10 and resists the first pin 10 from being pulled out.

Specifically, when the first switch 20 is in the pre-locked state, as shown in FIG. 23A, the first pin 10 is not inserted into the first switch 20, and the two balls/cylinders of the engaging member 22 in the first switch 20 fit each other. Consequently, as shown in FIGS. 23B-23C, the first pin 10 is inserted into the first switch 20, and the first switch 20 is in the locked state, and the first switch 20 locks the first pin 10 to resist the first pin 10 from being pulled out.

In some embodiments, the process of inserting the second pin 30 into the second switch 40 and controlling the second switch 40 to be in a locked state so that the second switch 40 locks the second pin 30 and resists further insertion of the second pin 30 includes the following.
S210: As shown in FIGS. 23A-23B, a magnetic field is applied to the second switch 40 to convert the second switch 40 from the unlocked state to the intermediate state. When the second switch 40 is in the unlocked state and/or the intermediate state, the second pin 30 is inserted into the second switch 40.
S220: As shown in FIG. 23C, the magnetic field is removed, so that the second switch 40 is converted from the intermediate state to the locked state, the second pin 30 is locked, and further insertion of the second pin 30 is resisted.

It should be noted that in Step S220, the magnetic field is quickly removed so that the elastic potential energy accumulated in the first sub-elastic member 431 is converted into the kinetic energy of the clamping part 420, so that each clamping part 420 moves quickly toward each other along the third inclined plane S3 under the elastic force of the connected first sub-elastic member 431 to clamp the second pin 30. Each clamping part 420 is accommodated in the space defined by the second pin 30, the third inclined plane S3 and the correspondingly connected first sub-elastic member 431, the second sub-elastic member 432 and the third sub-elastic member 433, thereby resisting further insertion of the second pin 30.
S300: As shown in FIG. 23D, each display unit 300 is placed on a same platform 600 from the display surface side of the display unit 300.

It should be noted that Step S200 is merely to detachably connect the support plate 200 with a display unit 300 attached to the bracket 100 through the first pin 10 and the first switch 20 as well as the second pin 30 and the second switch 40, but the display surface of each display unit 300 may not be in the same plane. In following Step S300 as shown in FIG. 23D, from the display surface side of the display unit 300, when the display units 300 are placed on the same platform 600, the splicing of different display units 300 may have a segmental difference. This can be caused by the different thicknesses of the different display units 300, or by the different distances between the support plates 200 and the bracket 100, or by the incline of the display units 300.
S400: As shown in FIG. 23E, by adjusting the locking height/depth of the first switch 20 to the first pin 10 and the locking height/depth of the second switch 40 to the second pin 30 between each support plate 200 and the bracket 100, the display surface of each display unit 300 is controlled to fit with the platform 600, thereby completing the splicing of each display unit 300.

From the above-described embodiments, it can be seen that by applying a magnetic field to the first switch 20, the first switch 20 is in an unlocked state, so that the first pin 10 may freely move in and out to adjust the height/depth. By applying a magnetic field to the second switch 40, the second switch 40 is in an unlocked state, so that the second pin 30 may freely move in and out to adjust the height/depth. After each display unit 300 is controlled to fit with the platform 600 under the action of gravity, the magnetic field is removed, and the first pin 10 is locked by the first switch 20, and the second pin 30 is locked by the second switch 40, so that the splicing of each display unit 300 is completed, and the display surface of each display unit 300 is as flat as the surface of the platform 600. Additionally, in the course of subsequent use, since the distance between the support plate 200 and the bracket 100 has been locked by the first pin 10 with the first switch 20 and the second pin 30 with the second switch 40, the display surface of each display unit 300 remains flat.

In some embodiments, the process of adjusting the locking height/depth of the first switch 20 to the first pin 10 between the support plate 200 and the bracket 100 includes:
S10: applying a magnetic field to the first switch 20 to convert the first switch 20 from a locked state to an unlocked state, thereby allowing the first pin 10 to move in and out freely; and
S20: after the display unit 300 is attached to the platform 600 under the action of gravity, removing the magnetic field to convert the first switch 20 from the unlocked state to the locked state, thereby locking the first pin 10 and preventing the first pin 10 from being pulled out.

In some embodiments, the process of adjusting the locking height/depth of the second switch 40 to the second pin 30 between the support plate 200 and the bracket 100 includes:
S30: applying a magnetic field to the second switch 40, and then removing the magnetic field, so that the second switch 40 is converted from the locked state to the unlocked state, thereby allowing the second pin 30 to move in and out freely;
S40: after the display unit 300 is attached to the platform under the action of gravity, applying a magnetic field to the second switch 40, and then removing the magnetic field, so that the second switch 40 is converted from the unlocked state to the locked state via the intermediate state, the second pin 30 is locked, and further insertion of the second pin 30 is resisted.

In some embodiments, a magnetic field may be applied to the first switch 20 and the second switch 40 via the platform 600, that is, the platform 600 may be an electromagnetic platform.

It should be noted that, in the present disclosure, the height/depth of the first pin 10 inserted into the first switch 20 is the height/depth of the first switch 20 locking the first pin 10. The deeper the first pin 10 is inserted into the first switch 20, the greater the height/depth of the first switch 20 locking the first pin 10, and the closer the distance between the support plate 200 and the bracket 100. The shallower the first pin 10 is inserted into the first switch 20, the lower the height/depth of the first switch 20 locking the first pin 10, and the farther the distance between the support plate 200 and the bracket 100.

Similarly, the height/depth of the second pin 30 inserted into the second switch 40 is the locking height/depth of the second switch 40 to the second pin 30. The deeper the second pin 30 is inserted into the second switch 40, the greater the locking height/depth of the second switch 40 to the second pin 30, and the closer the distance between the support plate 200 and the bracket 100. The shallower the second pin 30 is inserted into the second switch 40, the lower the locking height/depth of the second switch 40 to the second pin 30, and the farther the distance between the support plate 200 and the bracket 100.

It should be stressed that the locking height/depth of the first switch 20 to the first pin 10 may be adjusted arbitrarily, and the locking height/depth of the second switch 40 to the second pin 10 may also be adjusted arbitrarily. That is, the distance between the support plate 200 and the bracket 100 may be adjusted arbitrarily, and the flatness difference of the spliced display units 300 is generally within 1 mm, so that the display units 300 may be fully adjusted to eliminate the flatness difference of the spliced display units.

Compared with the existing technologies, the aforementioned technical solution provides the following advantages.

The locking device in the embodiments of the present disclosure includes a bracket and a support plate arranged opposite to each other, and the support plate is used to carry a display unit on the side away from the bracket. One of the bracket and the support plate includes a first pin and the other includes a first switch, when the first switch is in the locked state, the first pin is inserted into the first switch, and the first switch resists the first pin from being pulled out. One of the bracket and the support plate includes a second pin and the other includes a second switch, when the second switch is in the locked state, the second pin is inserted into the second switch, and the second switch resists the second pin from being further inserted.

In this way, during the installation and use of the display unit, after the flatness of the display surface of the display unit is adjusted, the first switch may be controlled to be in the locked state, and the first switch may be configured to resist the insertion of the first pin, thereby avoiding the increase of the distance between the bracket and the support plate. The second switch may be controlled to be in the locked state, and the second switch may be configured to resist the insertion of the second pin, thereby avoiding the decrease of the distance between the bracket and the support plate. That is, the distance between the bracket and the support plate is kept unchanged, thereby maintaining the flatness of the display surface of the display unit located on the side of the support plate away from the bracket unchanged, thereby improving the display performance.

The embodiments of the present disclosure are described in a combination of parallel and progressive ways. Each embodiment focuses on the differences from other embodiments, and the same or similar embodiments between the various embodiments may be referenced to each other.

The forgoing description are merely some embodiments of the present disclosure. Any person skilled in the art may easily think of changes or substitutions within the technical scope disclosed in the present disclosure, which should be included in the protection scope of the present disclosure. The protection scope of the present disclosure should be based on the protection scope of the claims.

What is claimed is:

1. A locking device, comprising a bracket and a support plate arranged opposite to each other, a side of the support plate facing away from the bracket being used for carrying a display unit, wherein:
one of the bracket and the support plate includes a first pin, and the other one of the bracket and the support plate includes a first switch, when the first switch is in a locked state, the first pin is inserted into the first switch, and the first switch resists the first pin from being pulled out; and
one of the bracket and the support plate includes a second pin, and the other one of the bracket and the support plate includes a second switch, when the second switch is in the locked state, the second pin is inserted into the second switch, and the second switch resists further insertion of the second pin.

2. The locking device according to claim 1, wherein the support plate includes at least two support plates.

3. The locking device according to claim 1, wherein the first switch comprises:
a first frame, wherein the first frame is provided with a first through-hole, the first through-hole allows the first pin to enter and exit, the first frame has a first accommodating space, the first through-hole is affixed to the first accommodating space, and a distance between at least a portion of an inner sidewall of the first frame gradually narrows in a direction toward the first through-hole;
an engaging member, wherein the engaging member is accommodated in the first accommodating space; and
a first elastic member, wherein the first elastic member is accommodated in the first accommodating space, is located at a side of the engaging member away from the first through-hole, and abuts against the engaging member,
wherein, when the first switch is in the locked state, the first pin passes through the engaging member and enters the first accommodating space, and the engaging member is accommodated in a space defined by the first pin, the first frame and the first elastic member to resist the first pin from being pulled out.

4. The locking device according to claim 3, wherein:
the inner sidewall of the first frame includes a first inclined plane which gradually narrows in the direction toward the first through-hole; and
when the first switch is in the locked state, an angle between the first pin passing through the engaging member and the first inclined plane is acute, and the engaging member is accommodated in the space defined by the first pin, the first inclined plane and the first elastic member to resist the first pin from being pulled out.

5. The locking device according to claim 4, wherein:
the engaging member is ferromagnetic; and
when the first switch is in an unlocked state, the engaging member abuts against the first elastic member, allowing the first pin to move in and out freely.

6. The locking device according to claim 3, wherein:
the first switch further includes a baffle, wherein the baffle is accommodated in the first accommodating space and is located between the engaging member and the first elastic member, and the first elastic member abuts against the engaging member through the baffle; and
the baffle is provided with a second through-hole, wherein the second through-hole corresponds to the first through-hole and allows the first pin to enter and exit.

7. The locking device according to claim 6, wherein:
the inner sidewall of the first frame includes a first inclined plane which gradually narrows in the direction toward the first through-hole;
a surface of the baffle abutting against the engaging member includes a second inclined plane, wherein the second inclined plane is arranged opposite to the first inclined plane; and
when the first switch is in the locked state, the first pin passing through the engaging member has an acute angle with the first inclined plane, and also has an acute angle with the second inclined plane, and the engaging member is accommodated in a space defined by the first pin, the first inclined plane and the second inclined plane to resist the first pin from being pulled out.

8. The locking device according to claim 7, wherein, when the first switch is in the locked state, a bisector of the angle between the first pin of the engaging member and the first inclined plane is perpendicular to the second inclined plane.

9. The locking device according to claim 6, wherein:
at least one of the engaging member and the baffle is ferromagnetic; and
when the first switch is in an unlocked state, the engaging member and the baffle push the first elastic member, thereby allowing the first pin to freely move in and out.

10. The locking device according to claim 9, wherein:
the engaging member includes two balls, when the first switch is in a pre-locked state, the first pin does not pass through the engaging member, and the two balls fit each other, when the first switch is in the locked state, the first pin passes through the engaging member and enters the first accommodating space, and the two balls are located on two opposite sides of the first pin and abut against the first pin; or
the engaging member includes two cylinders, when the first switch is in the pre-locked state, the first pin does not pass through the engaging member, and sidewalls of the two cylinders are in contact with each other, when the first switch is in the locked state, the first pin passes through the engaging member and enters the first accommodating space, the two cylinders are located on two opposite sides of the first pin, and the sidewalls of the two cylinders abut against the first pin.

11. The locking device according to claim 1, wherein the second switch comprises:
a second frame, wherein the second frame is provided with a third through-hole, the third through-hole allows the second pin to enter and exit, the second frame has a second accommodating space, the third through-hole is affixed to the second accommodating space, and an inner sidewall of the second frame includes a third inclined plane gradually narrowing in a direction away from the third through-hole;
a clamping member, wherein the clamping member is accommodated in the second accommodating space, the clamping member includes at least two clamping parts, and each of the clamping parts is arranged around the third through-hole; and
at least two sets of elastic assemblies, wherein the elastic assemblies are accommodated in the second accommodating space, the elastic assemblies and the clamping parts are connected one by one, the clamping parts are connected to the second frame through the elastic assemblies, and are held against the third inclined plane by the elastic assemblies,
wherein, when the second switch is in the locked state, the second pin enters the second accommodating space through the third through-hole and is clamped by each of the clamping parts, the clamping parts are accommodated in a space defined by the second pin, the third inclined plane and correspondingly connected elastic assemblies to resist further insertion of the second pin.

12. The locking device according to claim 11, wherein a clamping part has a fourth inclined plane, and the fourth inclined plane abuts against the third inclined plane.

13. The locking device according to claim 12, wherein:
the second frame includes a top and a sidewall, and the top is provided with the third through-hole;
an elastic assembly includes a first sub-elastic member, a second sub-elastic member and a third sub-elastic member;
the first sub-elastic member is connected between the top and a clamping part; and
the second sub-elastic member is connected between the sidewall and the clamping part, the third sub-elastic member is connected between the sidewall and the clamping part, and the second sub-elastic member and the third sub-elastic member are located on opposite sides of the clamping part.

14. The locking device according to claim 13, wherein:
at least part of the clamping part is magnetic, and a magnetic field of the clamping part has a component at least in a direction in which the bracket and the support plate are relatively arranged;
when the second switch is in an unlocked state, the first sub-elastic member, the second sub-elastic member and the third sub-elastic member connected to each of the clamping parts are pressed against the third inclined plane, allowing the second pin to freely move in and out;
when the second switch is in an intermediate state, each of the clamping parts abuts against the first sub-elastic member along the third inclined plane, allowing the second pin to freely move in and out; and
when the second switch is in the locked state, each of the clamping parts clamps the second pin, and each of clamping parts is accommodated in a space defined by the second pin, the third inclined plane, and the correspondingly connected first sub-elastic member, the second sub-elastic member, and the third sub-elastic member, thereby resisting further insertion of the second pin.

15. The locking device according to claim 11, wherein:
the clamping part has a clamping surface; and
when the second switch is in the locked state, the clamping surface of the clamping part abuts against the second pin, wherein the clamping surface is a flat or a curved surface.

16. The locking device according to claim 1, wherein:
the first pin and the first switch form a first damping group, and the second pin and the second switch form a second damping group;
when a single first damping group corresponds to a second damping group array formed by a plurality of second damping groups, a distance between a geometric center of the single first damping group and a geometric center of the corresponding second damping group array is less than a first predefined range;
when two first damping groups correspond to a second damping group array formed by a plurality of the second damping groups, a distance between a center of a line connecting geometric centers of the two first damping groups and a geometric center of the corresponding second damping group array is less than a second predefined range;
when a first damping group array formed by a plurality of the first damping groups corresponds to a second damping group array formed by a plurality of the second damping groups, a distance between a geometric center of the first damping group array and a geometric center of the corresponding second damping group array is less than a third predefined range;
when a first damping group array formed by a plurality of the first damping groups corresponds to a single second damping group, a distance between a geometric center of the first damping group array and a geometric center of the corresponding single second damping group is less than a fourth predefined range; or
when a first damping group array formed by a plurality of the first damping groups corresponds to two second damping groups, a distance between a geometric center of the first damping group array and a center of a line connecting geometric centers of the corresponding two second damping groups is less than a fifth predefined range.

17. The locking device according to claim 1, wherein the first pin and the second pin are an integrally formed structure, and the first switch and the second switch are stacked along a direction in which the bracket and the support plate are relatively arranged.

18. A display device, comprising a locking device, the locking device including a bracket and a support plate arranged opposite to each other, a side of the support plate facing away from the bracket being used for carrying a display unit, wherein:
one of the bracket and the support plate includes a first pin, and the other one of the bracket and the support plate includes a first switch, when the first switch is in a locked state, the first pin is inserted into the first switch, and the first switch resists the first pin from being pulled out;
one of the bracket and the support plate includes a second pin, and the other one of the bracket and the support plate includes a second switch, when the second switch is in the locked state, the second pin is inserted into the second switch, and the second switch resists further insertion of the second pin; and
the display device includes a display panel, wherein the display panel is located at a side of the support plate away from the bracket.

19. A splicing method, comprising:
respectively attaching a plurality of display units to their corresponding support plates, wherein display surfaces of the display units are located on a side of the display units away from the support plates;
detachably connecting each support plate to a bracket from a side of the support plate away from a display unit, wherein one of the bracket and the support plate includes a first pin, and the one of the bracket and the support plate includes a first switch, and by inserting the first pin into the first switch and controlling the first switch to be in a locked state, so that the first switch locks the first pin and resists the first pin from being pulled out, one of the bracket and the support plate includes a second pin, and the other one of the bracket and the support plate includes a second switch, and by inserting the second pin into the second switch and controlling the second switch to be in the locked state, so that the second switch locks the second pin and resists further insertion of the second pin;
placing each of the display units on a same platform from a display surface side of each display unit; and
by adjusting a locking height of the first switch to the first pin between each support plate and the bracket and a locking height of the second switch to the second pin, making the display surface of each display unit fit with the platform, thereby completing a splicing of each of the display units.

20. The splicing method according to claim 19, wherein adjusting the locking height of the second switch to the second pin between the support plate and the bracket comprises:
applying a magnetic field to the second switch and then removing the magnetic field to convert the second switch from the locked state to an unlocked state, thereby allowing the second pin to freely move in and out; and
after the display unit is attached to the platform under an action of gravity, applying the magnetic field to the second switch and then removing the magnetic field to convert the second switch from the unlocked state to the locked state via an intermediate state, thereby locking the second pin and resisting further insertion of the second pin.
